(19) United States
(12) Patent Application Publication
(10) Pub. No.: US 2012/0001336 A1
(43) Pub. Date: Jan. 5, 2012

(54) CORROSION-RESISTANT COPPER-TO-ALUMINUM BONDS

(75) Inventors: Kejun ZENG, Coppell, TX (US); Wei Qun PENG, Coppell, TX (US)

(73) Assignee: TEXAS INSTRUMENTS INCORPORATED, Dallas, TX (US)

(21) Appl. No.: 12/829,951

(22) Filed: Jul. 2, 2010

(51) Int. Cl. H01L 23/48

(52) U.S. Cl. 257/769; 257/741; 257/E23.01

(57) ABSTRACT

A connection formed by a copper wire (112) alloyed with a noble metal in a first concentration bonded to a terminal pad (101) of a semiconductor chip; the end of the wire being covered with a zone (302) including an alloy of copper and the noble metal in a second concentration higher than the first concentration. When the noble metal is gold, the first concentration may range from about 0.5 to 2.0 weight %, and the second concentration from about 1.0 to 5.0 weight %. The zone of the alloy of the second concentration may have a thickness from about 20 to 50 nm.

### FIELD OF THE INVENTION

The present invention is related in general to the field of metallurgical systems with application to electronic systems and semiconductor devices, and more specifically to the structure of semiconductor devices with aluminum-metallized contact pads contacted by ball bonds made from doped copper wires, and the reliability of these contacts under accelerated stress tests.

### DESCRIPTION OF RELATED ART

Among the standardized reliability test of electronic devices are a group of tests, which investigate the sensitivity of wire-bonded and packaged semiconductor devices to moisture. In these tests, statistical amounts of wire bonds are tested in moisture-free (dry) ambient and compared to statistical amounts of wire bonds in moist ambient. The moisture tests look for failures caused by corroded metals, weakened contacts, leakage and delamination of device packages, and degraded electrical characteristics under functional operation.

In the so-called THB test, the bonded units are subjected to 85% relative humidity at 85° C. under electrical bias for at least 600 hours, preferably 100 hours. In the so-called HAST test, the bonded units are subjected to 85% relative humidity at either 110° C. or 130° C. under electrical bias for at least 96 hours, preferably 250 hours. In the pressure test, the bonded units are subjected to 100% relative humidity at 121° C., unbiased, for at least 96 hours, preferably 240 hours. In these tests, the magnitude of the electrical bias is determined by the device type, and the number of allowed failures is determined by the customer for the intended application.

For many years, the quality and reliability of contact systems composed of gold balls made from gold wires, pressed onto contact pads of aluminum (or aluminum alloys) have been investigated in detail. It is known that four distinct compounds of gold/aluminum intermetallics can be formed, varying from aluminum-rich next the aluminum pads to gold-rich next to the gold ball. It was further found that when the contacts were properly formed, the intermetallics as a layer are mechanically stronger than both gold metal and aluminum metal, and thus bestow mechanical strength the gold-aluminum contacts. In addition it was found that gold-aluminum contacts with properly formed layers of gold/aluminum intermetallics pass the above described moisture tests, as long as aluminum corrosion is prevented by protecting the leftover aluminum against moisture attack, for instance by embedding the aluminum in adhering molding compound.

Stimulated by the recent steep increase in the price of gold, efforts have now started in the semiconductor industry to replace the traditional gold wires and gold balls by lower cost copper wires and copper balls. The technologies for forming free air balls from copper wires and forming copper-to-aluminum intermetallics after the copper ball touch-down on the aluminum pads have been solved to a great extent. The dominant intermetallic compounds are CuAl₂ on the side of the aluminum pad, and Cu₉Al₄ on the side of the copper ball; with enough temperature and annealing time, CuAl can form between them. The intermetallic compounds are mixed in a layer between the aluminum pad and the copper ball. Studies are now under way to test the reliability of the copper/aluminum contacts by subjecting them to the moisture test outlined above.

### SUMMARY OF THE INVENTION

Applicants evaluated statistical amounts of copper wire ball-bonds affixed to aluminum pads before and after moisture tests in order to determine the copper-to-aluminum ball-bond moisture reliability. The units had been subjected to standardized THB, HAST and pressure cooker tests, and thereafter subjected to standardized wire pull and ball shear tests. The results showed that copper wire bonds to aluminum pads deliver strong mechanical performance in dry tests but failed HAST at high rates (between 12 and 99%). All mal-functioning units failed by cracking through the interface between the copper ball and the aluminum pad.

Applicants micro-analyzed the failed units and found first of all that the cracking of the ball/pad interface occurred only in the positively biased device pins, but not in any of the grounded pins. Secondly, the layers of copper/aluminum intermetallic compounds between the aluminum pads and the copper balls were intact. After the times and temperatures of the moisture tests, the intermetallic layers were between about 1.0 and 1.5 μm thick and included as dominant intermetallic compounds CuAl₂ on the side of the aluminum pads and Cu₉Al₄ on the side of the copper balls CuAl between them.

Applicants further discovered between the intermetallic layer and the copper ball a thicker layer including a mixture of copper oxide (CuO and Cu₂O) and copper, with copper particles, but no aluminum, in the matrix of copper oxide. The observed cracking of a failed bond happened between this mixed layer and the copper ball. Applicants concluded that the root cause for the failure was the electrochemical corrosion of copper and the formation of a corrosion layer in the presence of high voltage and moisture.

Applicants solved the problem of copper oxidation by protecting the copper ball, when a thin layer (about 20 to 50 nm) of copper alloy enriched with a noble metal such as gold and palladium is enabled to grow in-situ on the copper side of the interface with the intermetallic layer. This in-situ accumulation can be realized by adding a small amount (for instance 0.5 to 5.0 weight %) of gold or palladium into the copper wire. After the doped copper ball, formed on the doped copper wire, is pressed onto the aluminum pad, a thin layer (about 50 to 100 nm) of copper/aluminum intermetallics will form at the interface as usual. For this formation of the intermetallic layer, copper atoms are taken into the intermetallic layer, leaving the noble atoms (either gold or palladium) behind. The more intermetallic compounds form (to a thickness of about 1.0 to 1.5 μm after HAST), the more atoms of gold pr palladium will be accumulated at the interface as a layer (about 100 to 200 nm thick) of Au- or Pd-enriched copper alloy on the copper ball. This alloy layer has a higher electrode potential and will act as a protective coating for the copper ball against electrochemical attack.

It is a technical advantage that copper wires doped with small amounts of gold or palladium can readily be supplied by vendors and can easily be implemented, because no new equipment for bonding is required and no change of the assembly flow process is needed.

It is another technical advantage that the high reliability of copper-bonded semiconductor devices by implementing the invention opens a wide window for selecting suitable molding compounds, packaging processes, device designs, and cost reduction.

### BRIEF DESCRIPTION OF THE DRAWINGS

FIG. 1 shows a schematic cross section of a copper ball bond on an aluminum pad in a packaged semiconductor device. The dashed outline indicated the enlargements of FIGS. 2 to 6.

FIG. 2 is a schematic cross section of a portion of a copper ball in contact with an aluminum pad at the beginning of a bonding process.

FIG. 3 depicts schematically the formation of interface layers after bonding a doped copper ball to an aluminum pad: a layer of copper/aluminum intermetallic compounds at the aluminum pad and a layer enriched with a noble metal at the doped copper ball.

FIG. 4 shows schematically the growth of the layer enriched with a noble metal at the doped copper ball during the time and temperature of the HAST; the enriched layer protects the doped copper ball against oxidation.

FIG. 5 illustrates schematically the formation of a layer of copper/aluminum intermetallic compounds at the interface of a ball of pure copper and an aluminum pad after a bonding process.

FIG. 6 shows schematically the growth of a layer of mixed copper oxide and copper between the intermetallic layer and the pure copper ball during the time and temperature of the HAST.

### DETAILED DESCRIPTION OF THE PREFERRED EMBODIMENTS

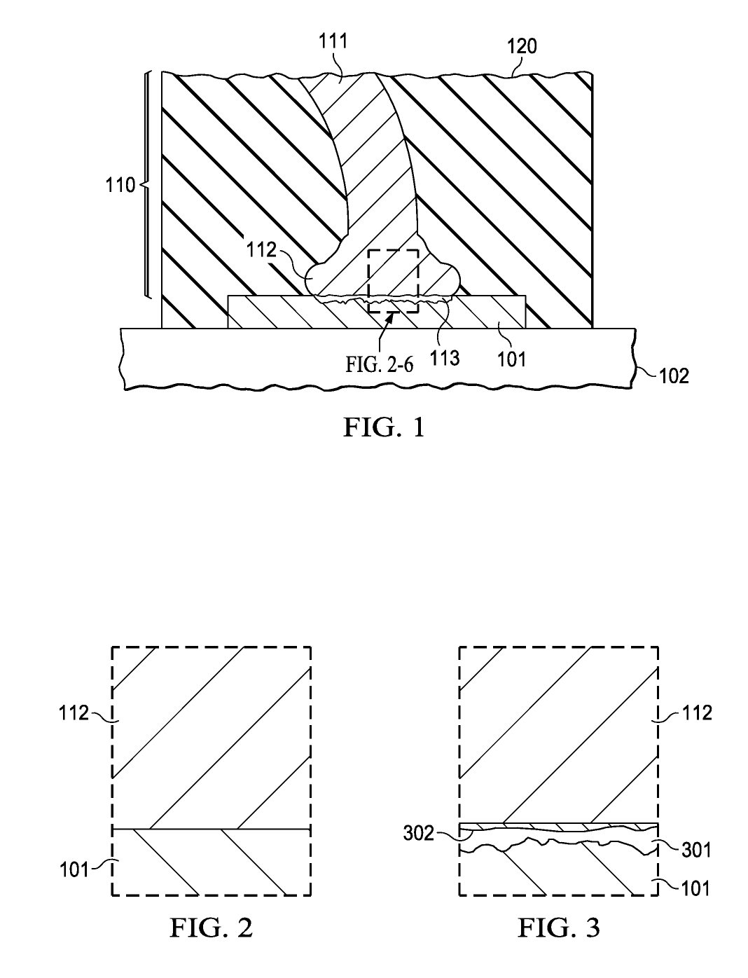

FIG. 1 displays schematically a terminal pad 101 of a semiconductor chip 102 contacted by a connecting wire 110. Terminal pad 101 is made of aluminum, often alloyed with 0.5 to 2% copper and/or 0.5 to 1% silicon. The pad is about 0.4 to 1.5 μm thick. Under the aluminum (not shown in FIG. 1) is frequently a thin layer (4 to 20 nm thick) of titanium, titanium nitride, titanium tungsten, tantalum, tantalum nitride, tantalum silicon nitride, tungsten nitride, or tungsten silicon nitride.

In FIG. 1, the connecting wire 110 includes a portion 111 of the round wire with a first diameter between about 15 to 33 μm, preferably 20 to 25 μm, and an end portion with a second diameter greater than the first diameter. Due to its shape, the end portion is often referred to as the wire nail head or the squashed wire sphere or ball. The wire consists of copper with an alloyed admixture of a noble metal such as gold or palladium. Alternative alloy options include the noble metals platinum and silver; other alloy options include more than one noble metal. The noble metal is uniformly alloyed with the copper in a first concentration preferably ranging from about 0.5 to 0.2 weight %. Uniformly alloyed wires are sometimes referred to as doped wires.

It should stated that the term noble metal is used herein to refer to a metal having a higher electrochemical potential than copper. Expressed relative to hydrogen, which by definition has the potential 0.0 V, the normal potential of copper is +0.337 V, and the following metals are “more noble”: silver +0.7991 V, mercury +0.854 V, palladium +0.987 V, platinum +1.2 V, and gold +1.498 V. In contrast, the normal potential of aluminum is −1.662 V. Consequently, if left unprotected, aluminum will give off electrons and form an oxide layer, which is self-limiting and protects the aluminum from further oxidation.

As FIG. 1 suggests, in a semiconductor device pad 101 with the attached wire 110 is encapsulated in a polymeric encapsulation compound 120, preferably in an epoxy-based molding compound filled with inorganic particles such as silicon dioxide in the range from about 80 to 90 weight %.

The wire bonding process begins by positioning the semiconductor chip 102 with the aluminum pad 101 on a heated pedestal to raise the temperature to between 150 and 300° C. Ball formation and bonding need to be performed in a reducing atmosphere, preferably including dry nitrogen gas with a few percent hydrogen gas. The wire is strung through a capillary. At the tip of the wire of first diameter, a wire end of second diameter greater than the first diameter, usually a free air ball is created using either a flame or a spark technique. The ball has a typical diameter from about 1.2 to 1.6 wire diameters. The capillary is moved towards the chip bonding pad 101 and the ball is pressed against the metallization of the pad. For pads of aluminum, a combination of compression force and ultrasonic energy creates the progressing formation of copper-aluminum intermetallics 113 and thus a strong metallurgical bond. The compression (also called Z- or mash) force is typically between about 17 and 75 gram-force/cm² (about 1670 to 7355 Pa); the ultrasonic time between about 10 and 30 ms; the ultrasonic power between about 20 and 50 mW. At time of bonding, the temperature usually ranges from 150 to 300° C. The bonding process results in the copper nail head or squashed ball illustrated in FIG. 1. A fragmentary portion of the copper-to-aluminum bond is marked by dashed lines in FIG. 1; the portion is enlarged in FIGS. 2 to 6 to discuss the changes at the bondline during the stages of the bonding process.

FIG. 2 displays the beginning of the bonding process, when the copper ball 112, uniformly doped with a noble metal (preferably gold or palladium), has been brought to contact with the aluminum pad 101. The surfaces both of copper ball 112 and aluminum substrate 101 are free of contaminants such as oxides, insulating layers, and particulate impurities. As stated above, the contact between copper ball and aluminum pad is achieved while the copper ball is under pressure and while energy is applied to the contact; one portion of the energy is thermal, provided by the elevating the temperature 150 to 200° C., and the other portion is ultrasonic energy, provided by the ultrasonic movement of the copper ball relative to the aluminum pad.

FIG. 3 depicts the contact interface after a period of time (between about 10 and 20 ms) since turning-on the ultrasonic movement. Thermal and ultrasonic energy have caused the interdiffusion of copper and aluminum atoms at the interface to create a layer 301 of intermetallic compounds in the thickness range from about 50 to 100 nm. While six copper/aluminum intermetallic compounds are known, the dominant compounds include CuAl₂ at the side of the aluminum pad 101, and Cu₉Al₄ at the side of the copper ball 112; in addition, CuAl is formed between these compounds when the time span of ultrasonic agitation is sufficiently long.

During the formation of the intermetallic layer 301, copper atoms are taken into the intermetallic layer, leaving the noble atoms (gold or palladium for the preferred copper wire alloy) behind. Consequently, the concentration of noble metals is enriched to about 1.0 to 5.0 weight % within the copper ball layer 302 nearest the bond-line interface having a layer thickness (about 20 to 50 nm) on the order of the diffusion distance of the copper atoms. The enriched concentration of noble metals in the layer coating the copper ball is herein referred to as second concentration (about 1.0 to 5.0 weight %); this concentration is higher than the first concentration (about 0.5 to 2.0 weight %) of noble metals in the original doped copper wire. The more intermetallic compounds form, the more noble atoms (gold or palladium) will be accumulated at the interface as a layer of gold- or palladium-enriched copper alloy on the copper ball, and the more the thickness of layer 302 will grow.

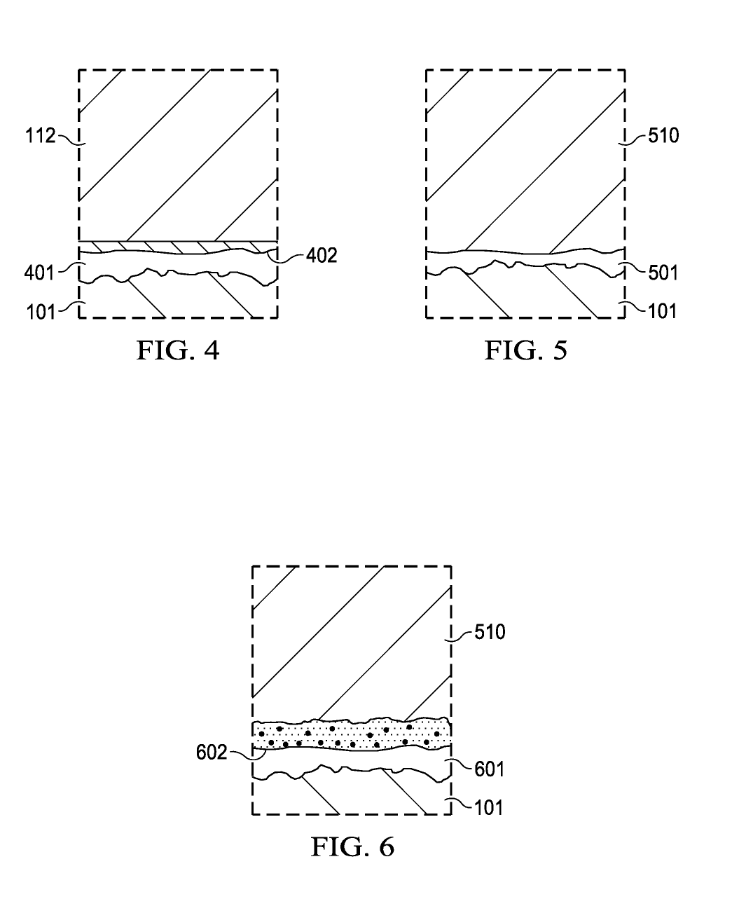

Alloy layer 302 has a higher electrode potential and will consequently act as a protective coating for the copper ball 112 against electrochemical attack in a moisture-related reliability test. As FIG. 4 indicates, during the time span and at the temperature of such test, the thickness of layer 302 (about 20 to 50 nm) of the noble metal with the second concentration may grow to become the thickness (100 to 200 nm) of noble metal-enriched layer 402. Concurrently, the thickness of layer 301 (about 50 to 100 nm) of intermetallic compounds may grow to a thickness of about 1.0 to 1.5 μm of intermetallic layer 401.

Semiconductor devices with aluminum bond pads and ball-bonded by copper wires doped with a metal more noble than copper, such as gold or palladium, pass the moisture-related THB, Hast, and pressure cooker reliability tests without failures and retained the original bond strength of the copper wire bonds. The layer of accumulated noble metal concentration coating the copper ball protect the copper ball against oxidation and corrosion.

In contrast, in samples where the copper ball 510 has been formed from a wire made of pure copper undoped by metals with an electrochemical potential more positive than that of copper, only a layer 501 of intermetallic compounds is readily formed by the bonding process to aluminum pad 101, see FIG. 5. The intermetallic compounds have the same chemical composition as quoted above. However, due to the nonexisting doping with a more noble metal, no thin layer enriched with noble metals can form to coat the copper ball 510.

As FIG. 6 shows, as a consequence of the humidity, times and temperatures of the moisture tests, a layer 602 thicker than the intermetallic layer 601 grows between the intermetallic layer and the copper ball 510; layer 602 includes a mixture of copper monoxide, copper dioxide, and copper, and particulate copper, but is deficient of aluminum. Layer 692 is a copper oxide and corrosion layer. In spite of its thickness, layer 602 is mechanically weak and allows the bonded copper ball to come easily from the aluminum pad in bond pull and sheer tests. Standard remedies cannot be applied: To prevent moisture from penetrating the package and reaching the copper wire bonds would be counterproductive to moisture testing; and to reduce the voltage is against the device design and device specifications.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to doped copper wire contacts to any aluminum pad, whether pure or doped aluminum, as long as intermetallics are formed, which consume copper atoms and thus provide a method to enrich the concentration of left-over noble metal atoms in the region near the interface to the intermetallics.

Further, the invention applies to contacts formed by copper wires, alloyed in a first concentration with a metal electrochemically more positive than copper, to zinc and tin (and silicon), when these contacts are subjected to HTB and HAST tests while positively biased. Copper forms intermetallic compounds of various lattice configurations with zinc and tin, including CuZn, Cu₅Zn₈, and CuZn₃; Cu₅Sn; Cu₃₁Sn₈, and Cu₃Sn. The copper atoms needed to form these compounds in the intermetallic layer move to the interface and leave the noble metal enriched in a second concentration higher than the first concentration in a coat around the copper wire end, protecting the copper from corrosion.

It is therefore intended that the appended claims encompass any such modifications or embodiments.

We claim:

1. A connection comprising:
a copper wire alloyed with a noble metal in a first concentration, the wire bonded to a terminal pad of a semiconductor chip; and
the wire having an end covered with a zone including an alloy of copper and the noble metal in a second concentration higher than the first concentration.

2. The connection of claim 1 wherein the noble metal is selected from a group including gold, palladium, platinum, and silver.

3. The connection of claim 2 wherein the noble metal in the first concentration ranges between about 0.5 to 2.0 weight % of the alloy.

4. The connection of claim 3 wherein the noble metal in the second concentration ranges from about 1.0 to 5.0 weight % of the alloy.

5. The connection of claim 4 wherein the zone of the alloy of the second concentration has a thickness from about 20 to 50 nm.

6. The connection of claim 1 further including a layer between the zone at the wire end and the chip terminal pad of aluminum, the layer including aluminum, copper, and aluminum/copper alloys wherein the dominant alloys comprise CuAl₂, Cu₉Al₄, and CuAl intermetallic compounds, metallurgically attached to the aluminum area and the wire end.

7. The connection of claim 1 wherein the wire has a first diameter and the wire end has a second diameter greater than the first diameter.
